(19) United States
(12) Patent Application Publication
(10) Pub. No.: US 2017/0263698 A1
(43) Pub. Date: Sep. 14, 2017

(54) POWER METAL-OXIDE-SEMICONDUCTOR DEVICE

(71) Applicant: BRIGHT TOWARD INDUSTRIAL CO., LTD., NEW TAIPEI CITY (TW)

(72) Inventors: KAO-WAY TU, New Taipei City (TW); YUAN-SHUN CHANG, New Taipei City (TW); TZU-HSU HSU, Taipei City (TW)

(21) Appl. No.: 15/190,957

(22) Filed: Jun. 23, 2016

(30) Foreign Application Priority Data
Mar. 9, 2016 (TW) 105107184

(51) Int. Cl. H01L 29/06; H01L 29/78

(52) U.S. Cl. CPC H01L 29/0634; H01L 29/0688; H01L 29/78

(57) ABSTRACT

A power metal-oxide-semiconductor (MOS) device is provided. The power MOS device is formed on a semiconductor substrate and includes an active region and a breakdown generated region. The active region includes a plurality of P-type doping regions and a plurality of N-type doping region alternatively arrayed between a source electrode and a drain electrode, and also includes a plurality of gate structures for controlling the conductive state of the active region. The breakdown generated region includes at least one P-type doping region and at least one N-type doping region alternatively arrayed between a source electrode and a drain electrode, and the breakdown voltage of the breakdown generated region is smaller than that of the active region.

### BACKGROUND OF THE INVENTION

1. Field of the Invention

The present invention is related to a power metal-oxide-semiconductor (MOS) device, and more particularly related to a power MOS device with super junction structure featuring low on resistance.

2. Description of Related Art

Super-junction MOS device is a power semiconductor device suitable for high frequency and high voltage applications, and is broadly used in various categories with the needs of high electric density, or high system efficiency and reliability.

The super junction MOS device includes a plurality of P-type pylons located in a N-type epitaxial layer extending along the depth direction of the N-type epitaxial layer. The P-type pylons are in parallel with each other and spaced apart with a predetermined interval. A plurality of gate structures is formed above the N-type epitaxial layer for controlling the conductive states of the channel between the source electrode above the epitaxial layer and the epitaxial layer (i.e. the drift region).

When the super junction MOS device is turned off, a depletion region is formed on the interface between the P-type pylons and the N-type epitaxial layer to block the current flowing from the source electrode to the drain electrode. To make sure the generated depletion region can block the conductive current thoroughly, dopant concentration of the P-type pylons and the N-type epitaxial layer should be adequately controlled to maintain the balance of P-type dopants and N-type dopants.

It is understood that on resistance (RDSON) of power MOS device is mainly decided by dopant concentration of the N-type epitaxial layer. For the traditional power MOS device without the super junction structure, dopant concentration of the epitaxial layer cannot be increased without limitation due to the need to meet the requirement of withstanding voltage. In contrast, because super junction power MOS device features the PN junction surfaces for forming the depletion regions to withstand the applied voltage, a higher dopant concentration of N-type epitaxial layer can be achieved without the need to consider the withstanding voltage. Therefore, the super junction power MOS device is superior to the traditional power MOS device, especially in the aspect of on resistance.

Energy during avalanche for single pulse (EAS) is an important parameter for a power MOS device, especially in the aspect of safety. This parameter represents tolerance of a power MOS device to withstand an applied voltage over the designed breakdown voltage. Because of the structural feature of super-junction, conventional super junction power MOS device has little capability to withstand avalanche energy, which may incur safety issues.

### SUMMARY OF THE INVENTION

As mentioned, the conventional super-junction power MOS device has little capability to withstand avalanche energy. Accordingly, a super-junction power MOS device is provided in the present invention, which features the additional breakdown-first area to enhance the capability for the MOS device to withstand avalanche energy.

Based on the aforementioned object, a power metal-oxide-semiconductor (MOS) device is provided in accordance with an embodiment of the present invention, the power MOS device is located on a semiconductor substrate and includes an active area and a breakdown-first area. The active area includes a plurality of active area P-type doping regions and a plurality of active area N-type doping regions alternatively arrayed between a source electrode and a drain electrode. The active area also includes a plurality of gate structures for controlling conductive state of the active area. The breakdown-first area includes at least a breakdown-first area P-type doping region and at least a breakdown-first area N-type doping region, alternatively arrayed between the source electrode and the drain electrode. Wherein drain-source breakdown voltage (BVDSS) of the breakdown-first area is smaller than that of the active area.

In accordance with an embodiment of the present invention, the power MOS device further includes a termination area surrounding the active region, and the breakdown-first area is located between the active area and the termination area.

In accordance with an embodiment of the present invention, the breakdown-first area includes a plurality of portions distributed in the active area. As a preferred embodiment, each of the portions is located between the neighboring gate structures.

In accordance with an embodiment of the present invention, a number of the breakdown-first area P-type doping region is greater than two and an interval of the neighboring breakdown-first area P-type doping regions is greater than that of the neighboring active area P-type doping regions, or a number of the breakdown-first area N-type doping region is greater than two and an interval of the neighboring breakdown-first area N-type doping regions is greater than that of the neighboring active area N-type doping regions, such that BVDSS of the breakdown-first area is smaller than that of the active area.

In accordance with an embodiment of the present invention, dopant concentration of the breakdown-first area N-type doping region is greater than that of the active area N-type doping region, such that BVDSS of the breakdown-first area is smaller than that of the active area.

In accordance with an embodiment of the present invention, the breakdown-first area N-type doping region has a width varied along a depth direction thereof, such that BVDSS of the breakdown-first area is smaller than that of the active area. As a preferred embodiment, the width of the breakdown-first area N-type doping region increases or decreases along the depth direction thereof.

In accordance with an embodiment of the present invention, intervals of the breakdown-first area N-type doping regions or the breakdown-first area P-type doping regions are constant.

In accordance with an embodiment of the present invention, intervals of the breakdown-first area P-type doping regions increase along a direction from the active area to the termination area, or intervals of the breakdown-first area N-type doping regions increase along the direction from the active area to the termination area.

In order to further the understanding regarding the instant disclosure, the following embodiments are provided along with illustrations to facilitate the disclosure of the instant disclosure.

### BRIEF DESCRIPTION OF THE DRAWINGS

The present invention will now be specified with reference to its preferred embodiment illustrated in the drawings, in which:

FIG. 1 and FIG. 1A are top view and cross-section view of a power MOS device in accordance with a first embodiment of the present invention;

FIG. 2 is a schematic view of a power MOS device in accordance with a second embodiment of the present invention;

FIG. 3 is a schematic view of a power MOS device in accordance with a third embodiment of the present invention;

FIG. 4A to 4F are schematic views showing a fabrication method of a power MOS device in accordance with a first embodiment of the present invention; and

FIG. 5A to 5F are schematic views showing a fabrication method of a power MOS device in accordance with a second embodiment of the present invention.

### DETAILED DESCRIPTION OF THE PREFERRED EMBODIMENTS

There are various embodiments of the super junction power MOS device and fabrication method thereof in accordance with the present invention. The three preferred embodiments of the super junction power MOS device and the two preferred embodiment of the fabrication methods are mentioned in the following paragraph as an example.

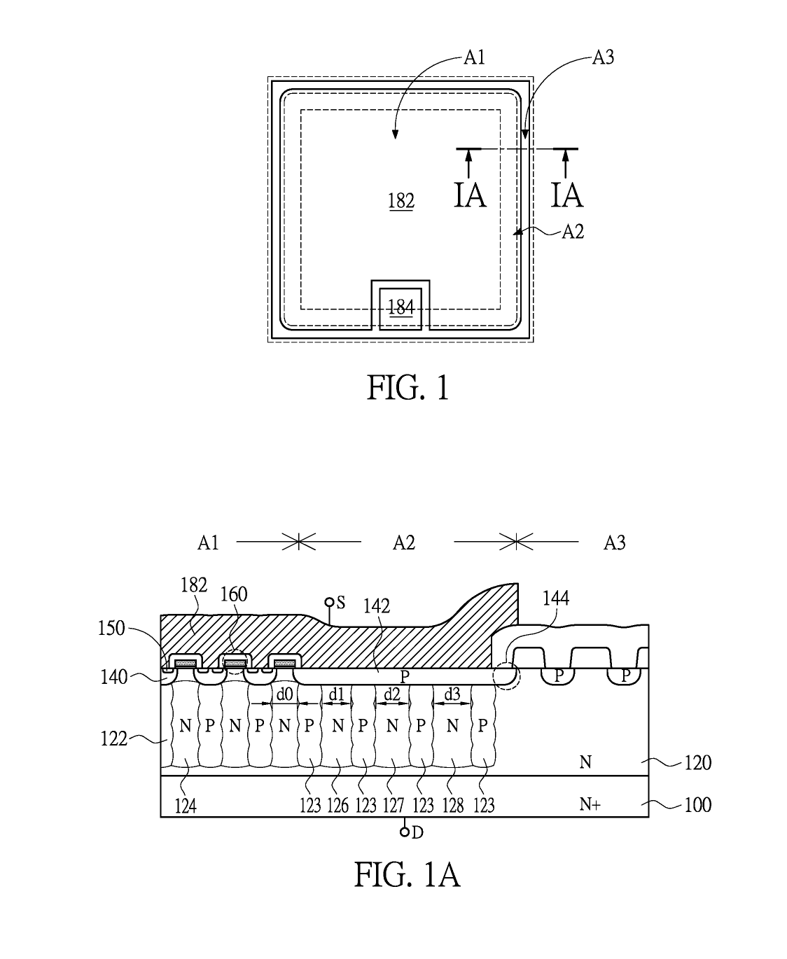

FIG. 1 and FIG. 1A are schematic views of a power MOS device in accordance with a first embodiment of the present invention, wherein FIG. 1 is a top view of the power MOS device, and FIG. 1A is a cross-section view of the power MOS device along cross-section IA-IA of FIG. 1. As shown, the power MOS device, such as a MOSFET, is formed on a N-type heavily-doped semiconductor substrate 100 and includes an active area A1, a breakdown-first area A2, and a termination area A3. The breakdown-first area A2 is located between the active area A1 and the termination area A3. A P-type channel stopper 144 is located between the breakdown-first area A2 and the termination area A3 to prevent the generation of parasitic channel.

As shown, the active area A1 is located in the center of the power MOS device (such as a chip), the breakdown-first area A2 surrounds the active area A1, and the termination area A3 surrounds the breakdown-first area A2 and is located near the edge of the power MOS device. It is noted that the above mentioned arrangement is merely an exemplary embodiment of the present invention, and the present invention is not so restricted. Because the function of the breakdown-first area A2 is to be a current path for releasing avalanche energy, the major concern for the arrangement of the breakdown-first area A2 is the area size, and it is not necessary to surround the active area A1 thoroughly as the termination area A3. For example, the breakdown-first area A2 can be arranged right below the gate pad 184 on the chip.

As shown in FIG. 1A, the active area A1 of the power MOS device includes a plurality of active area P-type doping regions 122 and a plurality of active area N-type doping regions 124 alternatively arrayed between a source electrode S and a drain electrode D of the power MOS device.

These alternatively arrayed P-type and N-type doping regions 122, 124 (i.e. the super junction structure) are located under the P-type body 140 to compose the drift region of the power MOS device for providing high withstanding voltage. In the present embodiment, the drain metal layer (not shown, but corresponding to the above mentioned drain electrode) is located on a lower surface of the N-type heavily-doped semiconductor substrate 100, the drift region is located above the N-type heavily-doped semiconductor substrate 100, the plurality of active area P-type doping regions 122 and the plurality of active area N-type doping regions 124 in the drift region are extended along the vertical direction, and the source metal layer 182 (corresponding to the source electrode) is located above the drift region.

In accordance with an embodiment of the present invention, the P-type doping regions 122 are pylon-shaped and distributed in the active area A1, and the N-type doping regions 124 surround the pylon-shaped P-type doping regions 122. However, the present invention is not so restricted. In accordance with another embodiment, for example, the N-type doping regions 124 may be pylon-shaped and distributed in the active area A1, and the P-type doping regions 122 surround the pylon-shaped N-type doping regions 124 to form the PN junction surfaces of the super junction structure. The above mentioned embodiments are suitable for the closed-cell power MOS device. In accordance with another embodiment of the present invention, which is suitable for the linear-cell power MOS device, these N-type doping regions 122 and P-type doping regions 124 are stripe-shaped and alternatively arrayed in the active area A1 from the top view.

The active area A1 of the power MOS device also includes a plurality of gate structure 160 for controlling the conductive state of the active area A1. In the present embodiment, the planar gate structure 160 located above the channel and the P-type body 140 is used, and the source doping region 150 is located in the P-type body 140. However, the present invention is not so restricted. Trench gate structures can also be used in the present invention for increasing cell density. The usage of trench gate structure is well known in the art and thus is not repeated here.

The breakdown-first area A2 of the power MOS device includes at least one breakdown-first area P-type doping region 123 (four P-type doping regions are shown in the figure as an example) and at least one breakdown-first N-type doping region 126, 127, 128 (three N-type doping regions are shown in the figure as an example) alternatively arrayed between the above mentioned source electrode and the drain electrode. These alternatively arrayed P-type doping regions 123 and N-type doping regions 126, 127, 128 (i.e. the super-junction structure) are located under a P-type doping region 142, which is corresponding to the P-type body 140 of the active area A1, and the extending directions of these doping regions are substantially identical to that of the P-type doping regions 122 and the N-type doping regions 124 in the active area A1. However, the breakdown-first area A2 does not include the gate structure 160 and the source doping region 150 of the active area A1. In addition, at least one parameter of the P-type doping regions 123 and/or N-type doping regions 126, 127, 128, such as width, shape, dopant concentration, etc., is different from that of the P-type doping regions 122 and/or N-type doping regions 124 in the active area A1 to make sure that drain-source breakdown voltage (BVDSS) of the breakdown-first area A2 is smaller than BVDSS of the active area A1. Thereby, when avalanche breakdown occurs, the current would be directed along the breakdown-first area A2 rather than the active area A1 first, such that the capability to withstand avalanche energy (i.e. the value of energy during avalanche for single pulse (EAS) of the power MOS device) can be enhanced. In addition, because no parasitic transistor is formed in the breakdown-first area A2, latch phenomena due to the breakdown of parasitic transistors can be prevented because the breakdown occurs in the breakdown-first area A2.

In the present embodiment, the intervals d1, d2, d3 of the neighboring breakdown-first P-type doping regions 123 (corresponding to the width of the breakdown-first N-type doping regions 126, 127, 128) are greater than the interval d0 of the neighboring active area P-type doping regions 122 to have BVDSS of the breakdown-first area A2 smaller than that of the active area A1. In addition, as a preferred embodiment of the present invention, the intervals d1, d2, d3 gradually increase along the direction from the active area A1 to the termination area A3 (i.e. d1<d2<d3). However, the present invention is not so restricted. As shown in FIG. 2, in the second embodiment of the power MOS device of the present invention, the interval d4 of the breakdown-first P-type doping regions 223 (corresponding to the width of the breakdown-first N-type doping regions 226) is greater than the interval d0 of the neighboring active area P-type doping regions 122 but remains constant.

In the above mentioned embodiments, the width of the P-type doping regions is kept constant but the intervals are varied to achieve the object for adjusting BVDSS. However, the present invention is not so restricted. In accordance with another embodiment of the present invention, the intervals of the P-type doping regions in the breakdown-first area A2 and that in the active area A1 are the same, but the interval of neighboring N-type doping regions in the breakdown-first area A2 (i.e. the width of the P-type doping region in the breakdown-first area A2) is greater than the interval of neighboring N-type doping regions in the active area A1, such that BVDSS of the breakdown-first area A2 would be smaller than that of the active area A1. In addition, in still another embodiment of the present invention, both the width of P-type doping regions and the width of N-type doping regions in the breakdown-first area A2 are modified to be greater than that of the P-type doping regions and the N-type doping regions in the active area A1, such that BVDSS of the breakdown-first area A2 would be smaller than that of the active area A1.

In the previous embodiments, the width of P-type doping regions and the width of the N-type doping regions are modified to lower down BVDSS of the breakdown-first area A2 so as to achieve the object of the present invention. It should be understood that the same object can be also achieved by increasing the width of the N-type doping regions and the width of the P-type doping regions in the active area A1. But the present invention is not so restricted. Besides the width of the P-type doping region and the N-type doping region, dopant concentration and dopant type of the doping regions may also influence the breakdown voltage of the super junction power MOS device. Thus, BVDSS of the breakdown-first area A2 may also be adjusted by changing the dopant concentration of the N-type doping regions and/or the P-type doping regions therein. For example, the N-type doping regions in the breakdown-first area A2 with higher dopant concentration can be used to reduce BVDSS of the breakdown-first area A2, or the dopant concentration of the P-type doping regions and/or N-type doping regions can be adjusted to change the charge balance between the adjacent P-type doping region and the N-type doping region slightly to reduce BVDSS of the breakdown-first area A2, such that BVDSS of the breakdown-first area A2 would be smaller than that of the active area A1.

In the above mentioned embodiments, BVDSS of the breakdown-first area A2 is adjusted by changing the width or dopant concentration of the doping regions, but the width of the P-type doping regions 122, 123 or the N-type doping regions 124, 126, 127, 128 substantially remains constant along the depth direction, no matter in the breakdown-first area A2 or the active area A1, to facilitate the fabrication process. However, the present invention is not so restricted. It is found by the inventor that the shape of the doping region is also a factor affecting the breakdown voltage of the super junction structure. Thus, the width of the N-type doping regions in the breakdown-first area A2 or the P-type doping regions in the breakdown-first area A2 may be adjusted along the depth direction to reduce BVDSS of the breakdown-first area A2 such that BVDSS of the breakdown-first area A2 would be smaller than that of the active area A1. For example, the width of the N-type doping regions or the P-type doping regions in the breakdown-first area A2 may be gradually reduced or increased along the depth direction.

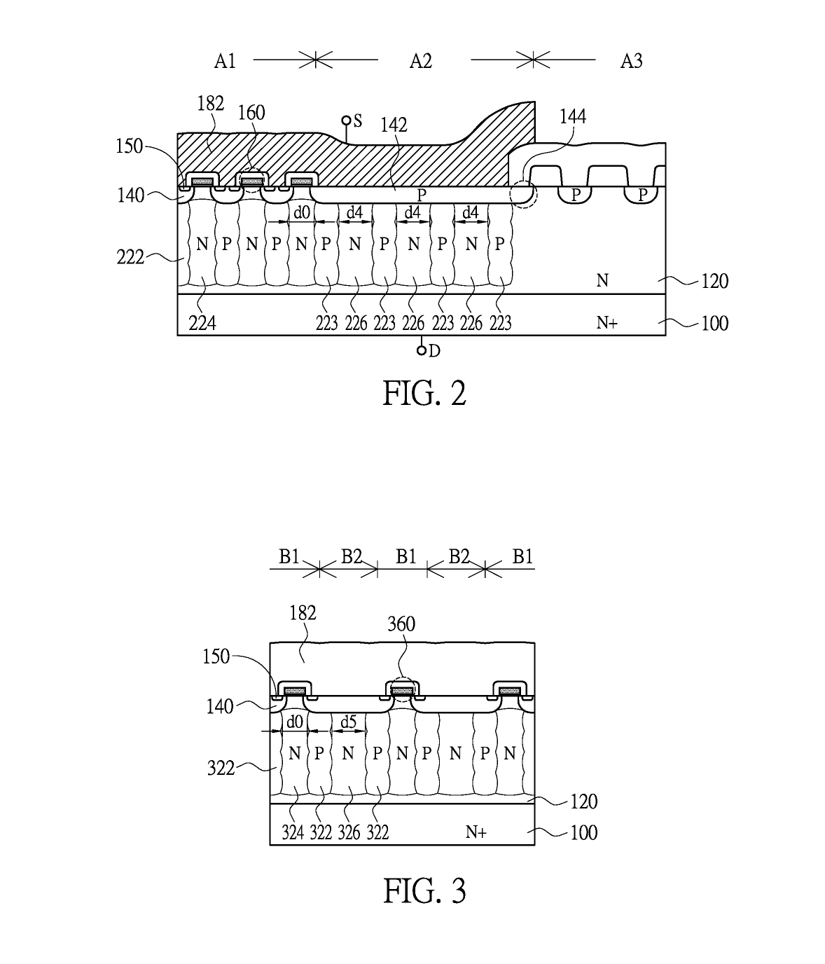

FIG. 3 is a schematic view of the power MOS device in accordance with a third embodiment of the present invention. As shown, in the present embodiment, an additional N-type doping region 326 is formed between two neighboring P-type doping regions 322 adjacent to two neighboring gate structures 360. Width d5 of the N-type doping region 326 is greater than width d0 of the N-type doping regions 324 right under the gate structures 360. The portion covered by the N-type doping region 326 and the two adjacent P-type doping regions 322 are regarded as the breakdown-first area B2. Thus, in the present embodiment, the breakdown-first area B2 of the power MOS device includes a lots of portions distributed in the active area B1 with a mesh structure. In detail, the active area B1 of the present embodiment is a net with a plurality of meshes, and the breakdown-first areas B2 are located in the meshes. As a preferred embodiment of the present invention, each of the portions of breakdown-first area B2 of the present embodiment is located between two neighboring cells in the active area B1.

In the above mentioned embodiment of the present invention, an additional N-type doping region 326 is formed between two neighboring gate structures 360 to compose the portion of breakdown-first area B2 including two P-type doping regions 322 and one N-type doping region 326. However, the present invention is not so restricted. In accordance with another embodiment of the present invention, multiple N-type and P-type regions can be alternatively arrayed between the two neighboring gate structures as the portion of the breakdown-first area of the power MOS device. The design of the P-type doping regions and N-type doping regions in the breakdown-first area B1 can be referred to the first and second embodiments of the power MOS device in the present invention and thus is not repeated here.

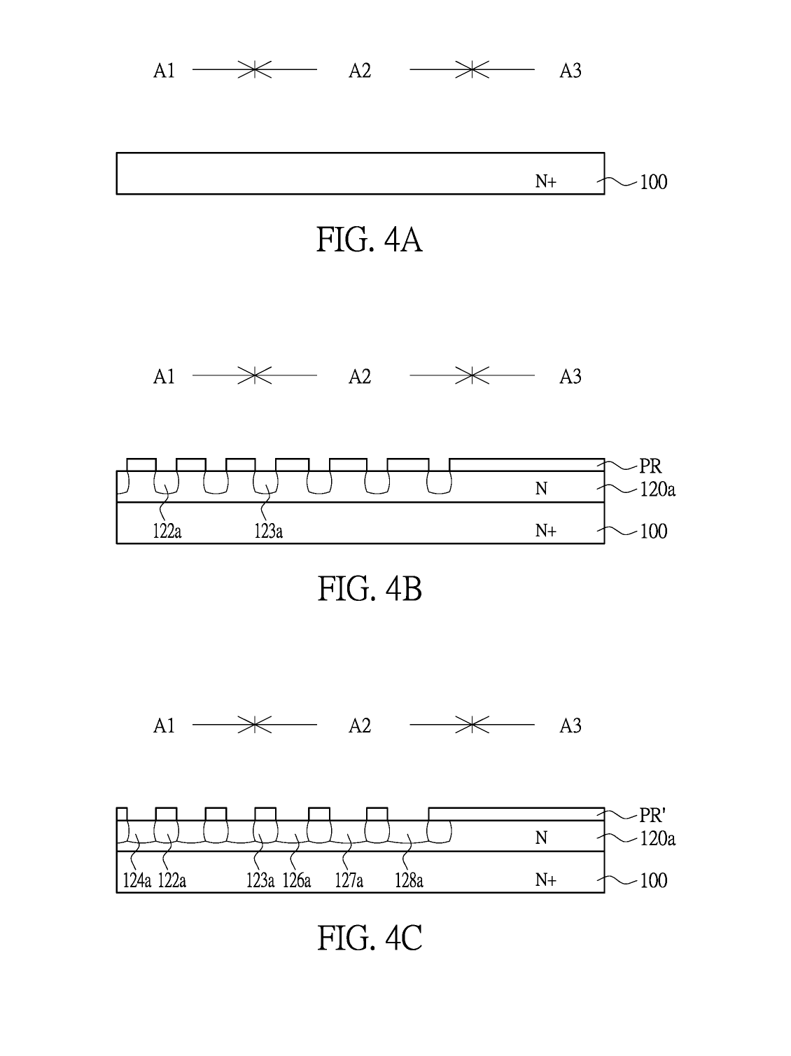

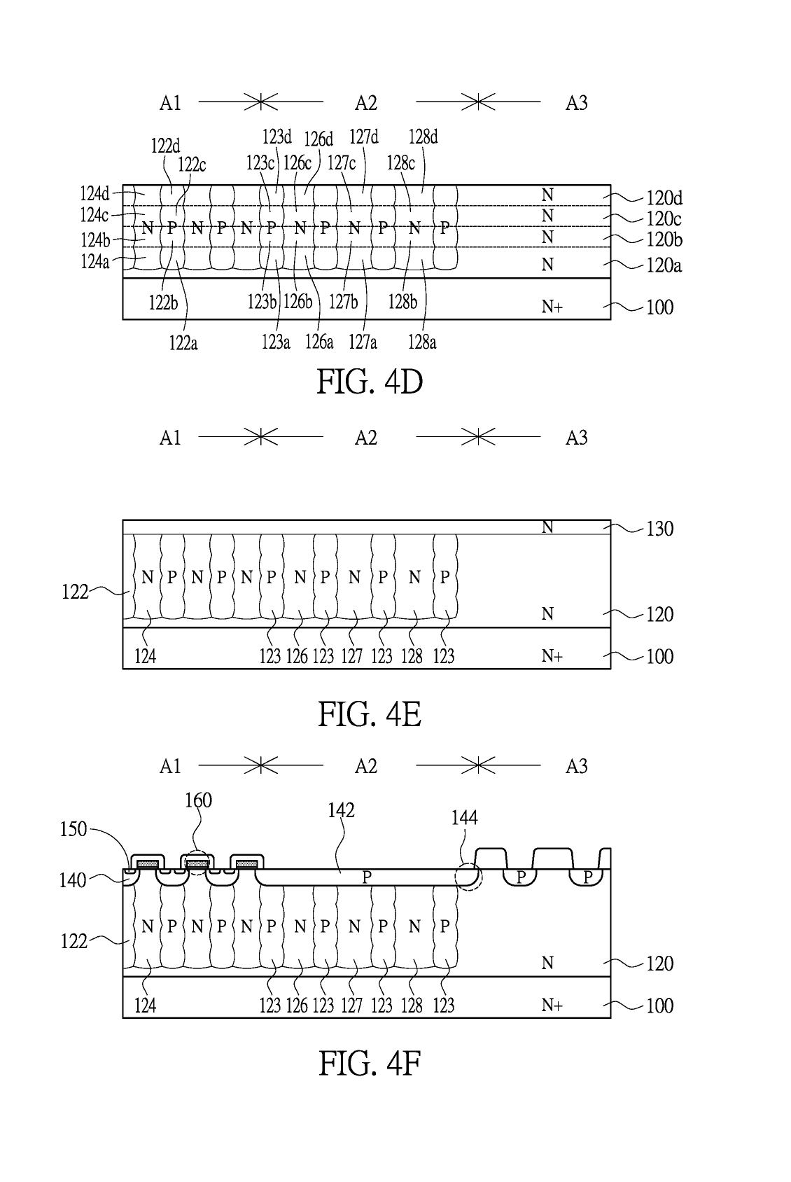

FIG. 4A to FIG. 4F are schematic views showing the fabrication method of the power MOS device in accordance with a first embodiment of the present invention. The fabrication method is corresponding to the power MOS device in FIG. 1.

As shown in FIG. 4A, firstly, an N-type heavily-doped substrate 100 is provided. Then, as shown in FIG. 4B, an N-type epitaxial layer 120a is formed on the N-type heavily doped substrate 100. Afterward, as shown in FIG. 4B, the P-type doping regions 122a of the active area A1 and the P-type doping regions 123a of the breakdown-first area A2 are defined on the N-type epitaxial layer 120a simultaneously by using a mask (corresponding to the photoresist pattern PR shown in the figure). Then, an ion implantation process is executed to form a plurality of P-type doping regions 122a, 123a in the N-type epitaxial layer 120a.

Afterward, as shown in FIG. 4C, the N-type doping region 124a of the active area A1 and the N-type doping regions 126a, 127a, 128a of the breakdown-first area A2 are defined on the N-type epitaxial layer 120a simultaneously by using another mask (corresponding to the photoresist pattern PR′ shown in the figure). Then, an ion implantation process is executed to form a plurality of N-type doping regions 124a, 126a, 127a, 128a between neighboring P-type doping regions 122a, 123a. Dopant concentration of these N-type doping regions 124a, 126a, 127a, 128a is higher than the original N-type epitaxial layer 120a.

Thereafter, as shown in FIG. 4D, the fabrication steps of FIG. 4B and FIG. 4C are repeated several times using the same masks (corresponding to the photoresist patterns PR and PR′) to form the drift region composed of a plurality of epitaxial layers 120a, 120b, 120c, 120d on the N-type heavily doped substrate 100. The P-type doping regions 122a-122d, 123a-123d, and the N-type doping regions 124a-124d, 126a-126d, 127a-127d, 128a-128d of each of the epitaxial layers 120a, 120b, 120c, 120d are aligned with each other.

Then, as shown in FIG. 4E, an N-type epitaxial layer 130 is formed on the drift region. Afterward, as shown in FIG. 4F, the body region 140 in the active area A1 and the doping region 142 in the breakdown-first area A2 are formed in the epitaxial layer 130. Then, the gate structures 160 are formed above the body region 140 and the source regions 150 are formed in the body region 140 so as to complete the fabrication process of the power MOS device.

The above mentioned fabrication method, which uses two masks (corresponding to two difference photoresist patterns PR and PR′) for forming the P-type doping regions 122a, 123a and the N-type doping regions 124a, 126a, 127a, 128a in the N-type epitaxial layer 120a respectively, is beneficial for the adjustment of charge balance between P-type doping regions 122a, 123a and the N-type doping regions 124a, 126a, 127a, 128a. However, the present invention is not so restricted. In accordance with another embodiment of the present invention, with the dopant concentration of the N-type epitaxial layer 120a being properly controlled, the mask for forming the photoresist pattern PR′ can be skipped, and the portions of the N-type epitaxial layer 120a shielded by the photoresist pattern PR can be used as the N-type doping regions directly.

In addition, the above mentioned fabrication method uses the same masks repeatedly to form the P-type doping regions 122, 123 and the N-type doping regions 124, 126, 127, 128 with a constant width which is not varied along the depth direction in the epitaxial layer 120. However, the present invention is not so restricted. In accordance with another embodiment of the present invention, the width or position of the N-type doping region or the P-type doping region at different depths may be adjusted by using a different mask or adjusting alignment slightly, such that the doping regions with a width varied along the depth direction can be generated for adjusting the breakdown voltage of the active area A1 or the breakdown-first area A2.

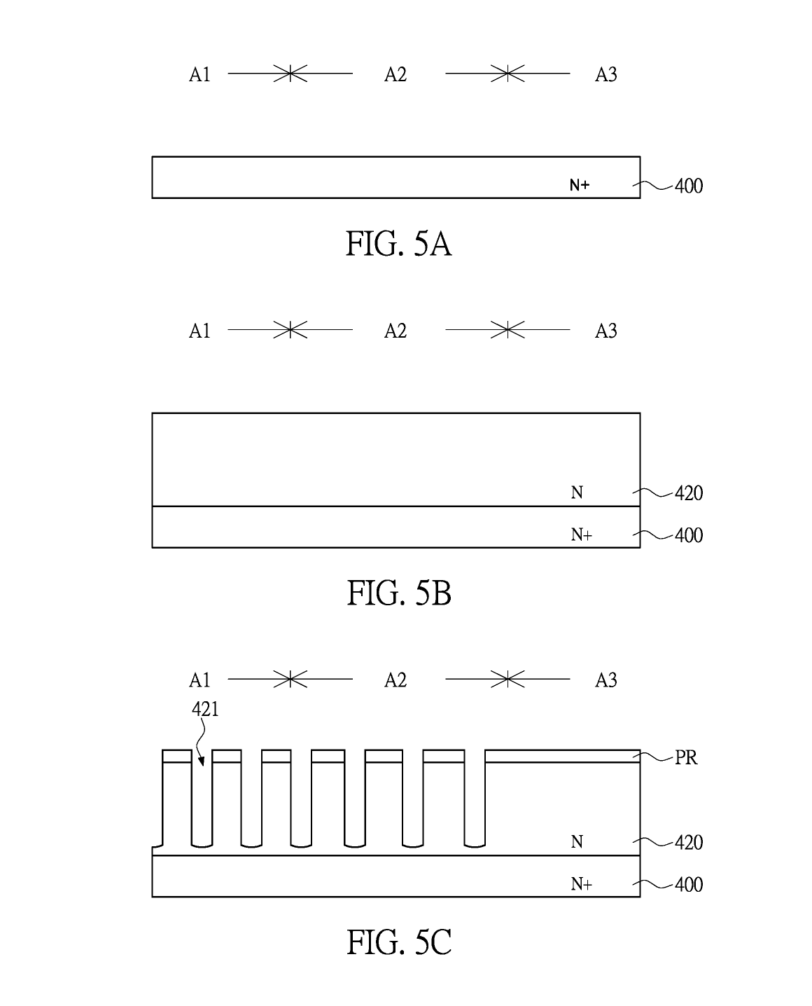

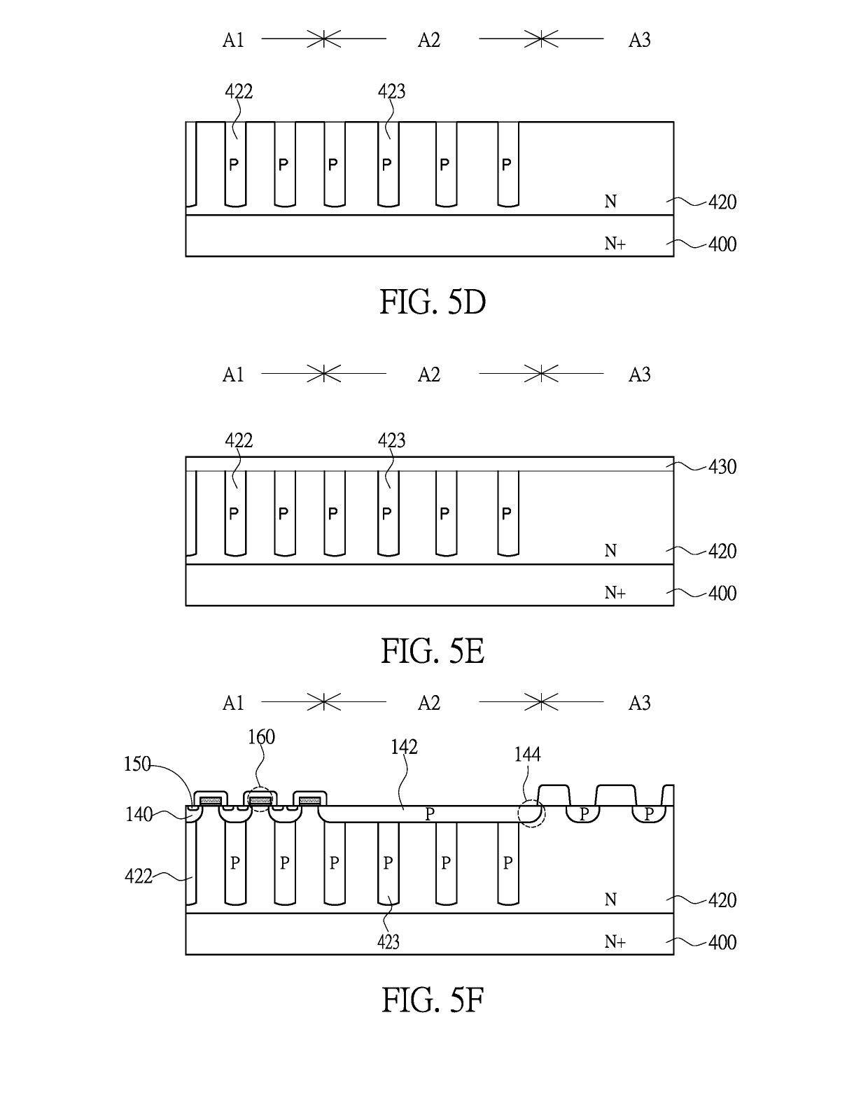

FIG. 5A to FIG. 5F are schematic views showing the fabrication method of the power MOS device in accordance with a second embodiment of the present invention. As shown in FIG. 5A, firstly, an N-type heavily-doped substrate 400 is provided. Then, as shown in FIG. 5B, a thick N-type epitaxial layer 420 is formed on the N-type heavily doped substrate 400. The thickness of the thick epitaxial layer 420 is a little greater than or the same as the thickness of the drift region of the power MOS device to be fabricated. Thereafter, as shown in FIG. 5C, the P-type doping regions 422 of the active area A1 and the P-type doping regions 423 of the breakdown-first area A2 are defined on the N-type thick epitaxial layer 420 simultaneously by using a mask (corresponding to the photoresist pattern PR as shown in the figure), and then a high energy anisotropic etching process is carried out to form a plurality of trenches 421 in the thick N-type epitaxial layer 420. Afterward, as shown in FIG. 5D, these trenches 421 are filled with P-type epitaxial material so as to form the active area P-type doping regions 422 and the breakdown-first area P-type doping regions 423.

Then, as shown in FIG. 5E, an N-type epitaxial layer 430 is formed on the thick N-type epitaxial layer 420. Afterward, as shown in FIG. 5F, the body region 140 in the active area A1 and the doping region 142 in the breakdown-first area A2 are defined in the epitaxial layer 430. Then, the gate structures 160 are formed above the body region 140 and the source regions 150 are formed in the body region 140 so as to complete the fabrication process of the power MOS device.

As mentioned, the conventional super junction power MOS device usually has the problem of little withstanding ability to avalanche energy. The problem can be resolved by using the super junction power MOS device in the present invention featuring the breakdown-first area to protect the active area so as to enhance the withstanding ability as the applied voltage is higher than the designed withstand voltage (i.e. the withstanding ability to avalanche energy). In addition, because the breakdown-first area has the structure similar to the active area except the gate structure and the source electrode, i.e. both the breakdown-first area and the active area have the drift region composed of alternatively arrayed P-type doping regions and the N-type doping regions, the fabrication process of the breakdown-first area can be integrated into the original fabrication process of the super junction MOS device without the need of additional fabrication step or too much additional cost.

The descriptions illustrated supra set forth simply the preferred embodiments of the instant disclosure; however, the characteristics of the instant disclosure are by no means restricted thereto. All changes, alterations, or modifications conveniently considered by those skilled in the art are deemed to be encompassed within the scope of the instant disclosure delineated by the following claims.

1. A power metal-oxide-semiconductor (MOS) device, located on a semiconductor substrate, comprising:
an active area including a plurality of active area P-type doping regions and a plurality of active area N-type doping regions alternately arrayed between a source electrode and a drain electrode, and including a plurality of gate structures for controlling a conductive state of the active area; and
a breakdown-first area including at least a breakdown-first area P-type doping region and at least a breakdown-first area N-type doping region alternately arrayed between the source electrode and the drain electrode;
wherein a drain-source breakdown voltage (BVDSS) of the breakdown-first area is smaller than that of the active area.

2. The power MOS device of claim 1, further comprising a termination area surrounding the active area, wherein the breakdown-first area is located between the active area and the termination area.

3. The power MOS device of claim 1, wherein the breakdown-first area includes a plurality of portions separated from one another.

4. The power MOS device of claim 3, wherein each of the portions of the breakdown-first area is located between each two adjacent gate structures respectively.

5. The power MOS device of claim 1, wherein a number of the at least one breakdown-first area P-type doping regions is greater than two and an interval between two adjacent breakdown-first area P-type doping regions is greater than that between two adjacent active area P-type doping regions of the plurality of active area P-type doping regions, or a number of the at least one breakdown-first area N-type doping regions is greater than two and an interval between two adjacent breakdown-first area N-type doping regions is greater than that between two adjacent active area N-type doping regions of the plurality of active area N-type doping regions.

6. The power MOS device of claim 1, wherein a dopant concentration of the breakdown-first area N-type doping region is greater than that of each of the plurality of the active area N-type doping regions, such that the BVDSS of the breakdown-first area is smaller than that of the active area.

7. The power MOS device of claim 1, wherein the breakdown-first area N-type doping region has a width varied along a depth direction thereof, such that the BVDSS of the breakdown-first area is smaller than that of the active area.

8. The power MOS device of claim 7, wherein the width of the breakdown-first area N-type doping region increases or decreases along the depth direction thereof.

9. The power MOS device of claim 2, wherein a number of the at least one breakdown-first area N-type doping regions or a number of the at least one breakdown-first area P-type doping regions is greater than two, the breakdown-first area N-type doping regions or the breakdown-first area P-type doping regions are equidistantly spaced apart from each other.

10. The power MOS device of claim 2, wherein a number of the at least one breakdown-first area P-type doping regions is greater than two, and intervals of the breakdown-first area P-type doping regions increase along a direction from the active area to the termination area, or a number of the at least one breakdown-first area N-type doping regions is greater than two and intervals of the breakdown-first area N-type doping regions increase along the direction from the active area to the termination area.

11. A power metal-oxide-semiconductor (MOS) device, located on a semiconductor substrate, comprising:
an active area including a plurality of active area P-type doping regions and a plurality of active area N-type doping regions alternately arrayed between a source electrode and a drain electrode, and including a plurality of gate structures for controlling a conductive state of the active area; and
a breakdown-first area including at least a breakdown-first area P-type doping region and at least a breakdown-first area N-type doping region alternately arrayed between the source electrode and the drain electrode, and the breakdown-first area includes a plurality of portions separated from one another;
wherein a drain-source breakdown voltage (BVDSS) of the breakdown-first area is smaller than that of the active area.

12. The power MOS device of claim 11, wherein each of the portions of the breakdown-first area is located between each two adjacent gate structures respectively.
